(19) United States
(12) Patent Application Publication
(10) Pub. No.: US 2026/0275516 A1
(43) Pub. Date: Sep. 17, 2026

(54) PRECURSOR DELIVERY DEVICE WITH HEATING ELEMENT AND RELATED METHODS

(71) Applicant: ENTEGRIS, INC., Billerica, MA (US)

(72) Inventors: Aravind Vasanthakumar, Singapore (SG); Subhash Guddati, Singapore (SG); Chengcheng Wang, Singapore (SG); Elsufyan Lukman, Singapore (SG); Montray Leavy, Singapore (SG); Jacob Thomas, Leander, TX (US)

(21) Appl. No.: 19/076,482

(22) Filed: Mar. 11, 2025

(51) Int. Cl. C23C 16/448; C23C 16/455; C23C 16/46

(52) U.S. Cl. CPC C23C 16/448; C23C 16/45561; C23C 16/46

(57) ABSTRACT

Described are precursor delivery ampoules that are useful for delivering gaseous precursor to a semiconductor manufacturing process, the delivery ampoules including a three-dimensional heating element that provides effective delivery of heat energy to the ampoule interior while having a small volume relative to the ampoule interior, as well as methods of making and using the heating element as part of a precursor delivery ampoule.

### FIELD

The following description relates to precursor delivery ampoules that are useful for delivering gaseous precursor to a semiconductor manufacturing process, the delivery ampoules including a three-dimensional heating element that provides effective delivery of heat energy to the ampoule interior while having a relatively small heating element volume compared to the ampoule interior, as well as methods of making and using the heating element as part of a precursor delivery ampoule.

### BACKGROUND

Chemical vapor deposition (CVD) techniques are used to deposit films and coatings onto substrates during semiconductor wafer processing. These techniques are effective to form highly conformal and high-quality films on three-dimensional surfaces. Examples of common chemical vapor deposition techniques include processes referred to as chemical vapor deposition (CVD) and atomic layer chemical vapor deposition (ALCVD or ALD).

Chemical vapor deposition techniques require a gaseous chemical precursor (“gaseous precursor”) to be delivered to a surface of a substrate, where the gaseous precursor is deposited onto the surface. The gaseous precursor is commonly produced and delivered by a precursor delivery device, e.g., a precursor delivery ampoule, which generates the gaseous precursor from a solid or liquid precursor material. The precursor material is held within an interior of the precursor delivery ampoule and is heated to produce the gaseous precursor, which is then delivered from the precursor delivery ampoule. In the case of a solid precursor material, the precursor is heated within the precursor delivery ampoule to form a gaseous precursor by sublimation. A carrier gas may optionally flow through the precursor delivery ampoule to carry the gaseous precursor from the precursor delivery ampoule. For a liquid precursor material, the liquid is also heated, and carrier gas is bubbled through the liquid to carry gaseous precursor from the precursor delivery ampoule.

### SUMMARY

The following description relates to precursor delivery ampoules, sometimes referred to as “delivery ampoules,” or simply “ampoules” for short, that are useful for delivering gaseous precursor to semiconductor manufacturing processing equipment, related methods and systems of using precursor delivery ampoules, and methods of preparing the precursor delivery ampoules.

Delivery ampoules as described include a heating element that distributes heat energy to the ampoule interior and to precursor material that is held at the ampoule interior. The heated precursor material forms a gaseous precursor that is delivered from the delivery ampoule for use in a semiconductor processing apparatus such as a vapor deposition apparatus. The precursor material from which the gaseous precursor is derived may be a solid precursor material or a liquid precursor material.

Common precursor delivery ampoules for producing a gaseous precursor from a solid precursor material (typically in the form of a granular powder) are designed to hold solid precursor material at the ampoule interior and deliver heat energy (“thermal energy”) to the ampoule interior from an external heat source. Typical designs include multiple, removable thermally-conductive trays that support the solid precursor material at multiple levels within the ampoule interior. The trays are thermally conductive and, in addition to supporting the solid precursor material, distribute heat within the ampoule interior.

Each thermally-conductive tray includes a horizontal surface that supports the solid precursor material. Heat that is generated outside of the ampoule passes by thermal conduction through the ampoule body (e.g., through ampoule sidewalls). The heat passes from the ampoule exterior, through the ampoule body, and eventually is distributed within the ampoule interior by the thermally-conductive trays. Solid precursor material heated by the trays sublimates to form a gaseous precursor. Openings in the horizontal tray surfaces allow the gaseous precursor, optionally in combination with a carrier gas, to circulate vertically within the ampoule interior and be delivered through a precursor outlet port that typically passes through a top (e.g., a “cover”) of the delivery ampoule, to deliver the gaseous precursor from the delivery ampoule.

These delivery ampoule designs are highly effective, as evidenced by their extensive use in commercial semiconductor processing. But these designs also exhibit inherent inefficiencies and performance deficiencies that, if identified and overcome, are opportunities for further improving delivery ampoule designs for still better performance. For example, certain inefficiencies are inherent in the use of multiple, removable thermally-conductive trays to support and heat a solid precursor material. The trays consume a significant amount of a total volume of an ampoule interior. The volume of the trays and any other structures that are located within an ampoule interior to facilitate delivery of gaseous precursor from the delivery ampoule reduces the amount of volume available for the solid precursor material.

As used herein, an amount (percent) of space within a delivery ampoule interior that is theoretically available to contain precursor material is referred to as a “theoretical fill volume.” The term “theoretical fill volume” refers to all space within an ampoule interior that is not taken up by structures that facilitate the delivery of gaseous precursor from the delivery ampoule such as heating elements (e.g., trays) and gas delivery devices such as conduits for a carrier gas. Precursor delivery ampoules that use replaceable trays may have a theoretical fill volume that is less than 75, 70, 65, or 60 percent, of the total interior volume of a delivery ampoule; i.e., the thermally-conductive trays of these designs may consume at least 25 percent of the total interior volume.

In practice, with a delivery ampoule that uses removable trays to support and heat solid precursor material, the amount (e.g., bulk volume) of solid precursor material that can be loaded into the ampoule interior may be significantly less that the theoretical fill volume. For various reasons, including the methods used to place trays and solid precursor material into a delivery ampoule interior, delivery ampoules that use heat-conducting trays are not able to contain an actual volume of solid precursor material that equals the theoretical fill volume, during use.

As compared to “theoretical fill volume,” an actual amount of solid precursor material that is loaded into a delivery ampoule during use can be referred to as the “actual fill volume,” or simply “fill volume.” As used herein, a “fill volume” or “actual fill volume” refers to a bulk volume of solid precursor material contained in an ampoule interior during use, per total interior volume of the ampoule interior. Precursor delivery ampoules that use multiple, replaceable thermally-conductive trays may contain a maximum amount of solid precursor material during use, i.e., a “fill volume” or “actual fill volume,” that is less than 50, 45, or 40 percent of the total interior volume of the ampoule.

The term “bulk volume” of a solid precursor powder is given its ordinary meaning as used in the semiconductor processing arts and refers to a volume of a mass of a bulk granular material, e.g., granular powder, meaning a volume of powder particles and space between the particles.

Semiconductor manufacturers prefer delivery ampoules that have relatively large fill volumes compared to those having smaller fill volumes, i.e., delivery ampoules that are capable of containing a large amount of solid precursor material during use. A large fill volume increases the efficiency of processes that use the delivery ampoule, e.g., by increasing the amount of time over which the delivery ampoule can continuously deliver gaseous precursor without being interrupted to add solid precursor material to the delivery ampoule.

In addition to the inherent inefficiency of a smaller fill volume, methods of loading solid precursor material and removable trays into a delivery ampoule also lack efficiency. Loading the trays and solid precursor material into an ampoule interior involves non-automated, manual handling of the trays and the solid precursor material within a controlled (clean) atmosphere. The controlled environment is required to prevent the solid precursor material from being exposed to potential contaminants. Common techniques involve placing the trays and the solid precursor material into the delivery ampoule while these are held within a controlled atmosphere of a “glove box” or a fume hood. The loading process is relatively time consuming, labor-intensive, and not easily adapted to automation.

As a performance deficiency, heat-conducting trays have a limited ability to distribute heat energy in a uniform manner throughout an ampoule interior. Non-uniform heating of the solid precursor material can produce non-uniform or inconsistent flux of gaseous precursor delivered from the precursor delivery ampoule.

One source of non-uniform heating is that the solid precursor material has limited contact with the tray surfaces and may not have good thermal conductivity. The horizontal tray surfaces are effective to a useful degree to distribute heat energy horizontally by conduction but have a limited ability to distribute heat vertically. Also, the trays rely on heat generated by an external heat source, often a heating jacket. The heat is conducted from the external heating jacket, through the ampoule body (sidewall), and then through the interior by conduction through the trays. When a heating jacket is used as an external source of heat, the heating jacket itself occupies space and reduces the amount of an ampoule footprint that would otherwise be available for precursor material. Moreover, certain heating jacket designs use heating rods to apply heat to the ampoule exterior. Spacing of the heating rods around the ampoule exterior produces a non-uniform heat flux applied to the ampoule exterior, which then transfers to the heat-conductive trays in a non-uniform fashion. Furthermore, effective conduction of heat energy from the heating jacket to the ampoule sidewall is highly dependent on the contact area at the interface between the heating jacket and the sidewall, which is not perfectly efficient.

Additionally, heat transferred from an external heat source requires an extended route of thermal energy conduction through the ampoule body and a large amount of heat being held by the ampoule body. This limits the ability to promptly increase or reduce the amount of heat delivered to an ampoule interior. Once the ampoule body is heated, heat energy will continue to be delivered to the ampoule interior even after the heating jacket is powered off, which can be undesired.

Accordingly, opportunities exist for improving the performance of precursor delivery ampoules. The following description relates to precursor delivery ampoules that address the above-described inefficiencies and performance deficiencies of previous delivery ampoule designs. Described as follows are three-dimensional heating elements and precursor delivery ampoules that can allow one or more of: a large fill volume (actual fill volume) of an ampoule; useful or advantageous distribution of heat within the ampoule interior; and improved methods of loading the ampoule interior. The heating elements may also include one or more additional features or advantages as also described herein. According to certain examples, a heating element may contain a flow channel adapted to deliver carrier gas from an exterior, through the flow channel, and to an ampoule interior. Alternately or additionally, example heating elements may incorporate a source of heat energy that generates or delivers heat energy within the heating element and delivers the heat energy directly into an ampoule interior without the heat energy passing by thermal conduction through the ampoule body (e.g., sidewall, bottom, or top).

According to examples, any of the generally or specifically described heating elements may be produced by an additive manufacturing process. An additive manufacturing process may be used to prepare the heating element and, optionally, to prepare a unitary, combined structure that includes the heating element structurally integrated with another component of a delivery ampoule, such as one or more of a bottom component, a top component, and/or a sidewall component.

In one aspect, the description relates to a precursor delivery ampoule adapted to generate a gaseous precursor useful in a vapor deposition process. The ampoule includes: an ampoule body comprising a sidewall, a top, and a bottom that define an ampoule interior; an outlet port that allows gaseous precursor to flow out of the ampoule interior; and a three-dimensional, thermally-conductive heating element contained in the ampoule interior, the heating element being prepared by an additive manufacturing method.

In another aspect, the description relates to a method of delivering gaseous precursor to a vapor deposition device. The method includes placing precursor material into an interior of precursor delivery ampoule comprising: an ampoule body comprising a sidewall, a top, and a bottom that define an ampoule interior; an outlet port that allows gaseous precursor to flow out of the ampoule interior; a three-dimensional thermally-conductive heating element contained in the ampoule interior, the heating element being prepared by an additive manufacturing method; sealing the ampoule interior; heating the precursor material to produce gaseous precursor; and delivering the gaseous precursor from the interior to a vapor deposition device.

### BRIEF DESCRIPTION OF THE DRAWINGS

FIGS. 1A and 1B show a side cross-sectional view and a top view of example components of an example precursor delivery ampoule as described.

FIGS. 2A and 2B show a side cross-sectional view and a top view of example components of an example precursor delivery ampoule as described.

FIGS. 3A, 3B, and 3C show side cross-sectional views of example components of example precursor delivery ampoules as described.

FIGS. 4A and 4B are photographs of top perspective views of an example three-dimensional heating element as described.

FIGS. 5A and 5B are photographs of a top perspective view and a top view of example components of an example precursor delivery ampoule as described.

FIGS. 6A and 6B are photographs of a side cut-away view and a perspective cut-away view of example components of an example precursor delivery ampoule as described.

FIG. 7A is a photograph of a top perspective view of an exemplary combined structure including a heating element and a top as described.

FIG. 7B is a cross-sectional view of a model of the combined structure shown in FIG. 7A.

FIG. 7C is a photograph of a top perspective view of an exemplary ampoule top as described.

FIGS. 8A and 8B shows an example of an ampoule body prepared by an additive manufacturing method. FIG. 8B is a cross-sectional view of the ampoule body of FIG. 8A taken along line A-A

The example components and delivery ampoules shown by the figures are exemplary and are not intended to limit the present description. The figures are schematic and not necessarily to scale.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

A precursor delivery ampoule is useful to deliver a flow of gaseous precursor to semiconductor processing equipment such as a chemical vapor deposition apparatus. The delivery ampoule contains precursor material, which may be a liquid precursor material or a solid precursor material, such as a granular solid powder precursor. The precursor material is held in the interior of the precursor delivery ampoule and is heated to produce the gaseous precursor, which is then delivered from the precursor delivery ampoule. In the case of a solid precursor material, the precursor material is heated to cause the solid precursor material to sublimate to form the gaseous precursor. A carrier gas may optionally be flowed through the interior of the delivery ampoule to carry the gaseous precursor from the delivery ampoule. For a liquid precursor material, the liquid is also heated, and carrier gas is bubbled through the liquid precursor to carry gaseous precursor derived from the liquid, from the precursor delivery module.

Solid precursor powder may be loaded into the ampoule interior at the top of the precursor delivery ampoule and will flow to the bottom and accumulate within the delivery ampoule, while the delivery ampoule contains the heating element. Solid (e.g., powder) precursor material that is introduced at the top of the ampoule interior can freely flow to the ampoule bottom past or over the heating element segments to completely fill the space of the theoretical fill volume of the ampoule. Preferred heating elements and heating element segments will allow for a flow of solid precursor material that is introduced at the top of the ampoule body to flow freely (optionally with agitation of the delivery ampoule) from the top to the to the bottom of the ampoule interior and to accumulate within the ampoule interior to substantially or completely fill the theoretical fill volume of the ampoule interior.

The following description relates to precursor delivery ampoules, sometimes referred to as “delivery ampoules,” or simply “ampoules” for short, that are useful for delivering gaseous precursor to semiconductor manufacturing processing equipment, related methods and systems of using precursor delivery ampoules, and methods of preparing the precursor delivery ampoules.

Precursor delivery ampoules include multiple identifiable structures (“components” or “ampoule components”) that together form a complete and operational delivery ampoule. These include basic components such as a heating element; a sidewall (typically cylindrical); a top or “cover”; and a bottom, below the sidewall.

The sidewall, top, and bottom may be referred to as an ampoule “body” and together define the ampoule interior that contains the heating element. During use to produce gaseous precursor from a liquid or solid precursor material, the precursor material is added or “loaded” into the ampoule interior to reside at the interior along with the heating element. The heating element delivers heat energy to the precursor material and the gaseous precursor material is derived from the heated precursor material. The gaseous precursor is delivered from the delivery ampoule for use in a semiconductor processing step. Optionally, a carrier gas can be passed through the ampoule interior to carry the gaseous precursor from the ampoule interior.

A three-dimensional heating element having a design that is generally or specifically described herein, or another useful design that may provide any of the presently-identified structural or performance advantages, may be formed by any useful manufacturing technique. An additive manufacturing method may be particularly useful for producing certain of the described heating elements or one or more individual components of a delivery ampoule. Optionally, an additive manufacturing method may be useful to produce a combined structure that includes the heating element in combination with one or more other components of a precursor delivery ampoule (e.g., bottom, top, or sidewall).

Additive manufacturing methods, sometimes referred to as “3D printing methods”, are used to produce three-dimensional objects from a computer aided design (CAD) model or a digital 3D model. Useful methods produce a three-dimensional article by sequentially depositing, solidifying, or joining (melting or sintering) multiple layers of a precursor material, one layer at a time, based on computer-controlled sequences and patterns that produce each individual layer. Layers are processed using steps suited for use with a particular type of precursor material. Example steps used to form individual layers include: polymerization (using heat or radiation); thermoplastic melting and solidification of a polymer; extrusion and deposition of a heated liquid, which may be polymeric or metal; particle bonding with heat, e.g., metal particle bonding using heat that is precisely directed and controlled from laser; and optional post-forming steps that may include de-binding, sintering, cleaning, and machining, among others. Additive manufacturing methods can be used to produce articles having a single, unitary structure meaning article having components that are secured to each other without any additional structure or additional assembly step such as a welding step, a mechanical connecting step (using mechanical fasteners), or a physical interlocking or adhesive connection or bond formed by a step other than the additive manufacturing process.

Various additive manufacturing techniques are known and can be adapted to produce a three-dimensional heating element (optionally as a combined structure that includes one or more other components of a delivery ampoule) having a design and advantages as described. Examples of known types of additive manufacturing techniques include laser powder bed fusion techniques (LPBF) that form a multi-layer three-dimensional article from a metal powder precursor material using heat from a laser; material jetting 3D printing techniques, e.g., metal material jetting techniques; stereolithography “SLA” techniques; as well as among others. One general class of additive manufacturing method may be referred to as “powder-bed” additive manufacturing methods, which include various “binder jet printing” techniques. Other examples include stereolithography techniques (SLA), selective laser sintering (SLS), and “fused deposition modeling” (FDM).

A heating element that is formed by an additive manufacturing process may include detectable layers that result from the individual steps used to form the heating element. If visible, these layers may appear as lines or striations at a surface of the three-dimensional article, each indicating a single layer of the article. The lines or striations have a substantially uniform thickness and indicate a planar layer of the article that extends over the two dimensions transverse to the thickness, e.g., width and length. The lines or striations may be visible without the need for magnification or may be visible with magnification as an aid. Lines or striations that exist at an article surface may be made less visible by processing (e.g., machining, finishing) the surface after the article has been initially produced by the additive manufacturing process.

Useful delivery ampoules include an ampoule body that includes a sidewall, a top, and a bottom that together define an ampoule interior (the sidewall, top, and bottom, as well as a three-dimensional heating element may be referred to separately or collectively as “ampoule components” or “components”). The ampoule components can be prepared from materials that are compatible for use within a precursor delivery ampoule used to deliver gaseous precursor derived from a liquid or solid precursor material, optionally with the assistance of a carrier gas. The components can be prepared from materials that exhibit high thermal conductivity, such as a metal.

During use, the ampoule body encloses and seals the ampoule interior, which contains the heating element and precursor material. The ampoule body may include one or more openings (sometimes referred to as “ports”) that are adapted to allow movement of one or more fluids between the ampoule interior and an exterior of the delivery ampoule. The ampoule body may include a delivery port that allows gaseous precursor (optionally carried by a carrier gas) to be delivered from the ampoule. The delivery ampoule may optionally include a carrier gas inlet port to deliver carrier gas to the ampoule interior from an external source. An ampoule body as described may also include a precursor fill port (or “fill port”) that is adapted to allow precursor material to be added (“loaded”) into the ampoule interior, optionally using equipment that prevents the precursor material from being exposed to an outside (exterior) atmosphere. The one or more ports of the delivery ampoule are typically in the form of openings that extend through the top of the ampoule body.

According to some examples, the ampoule components (top, bottom, sidewall, heating element) may take the form of individual, separate (separable) component structures that are produced individually by multiple separate manufacturing processes. Each component may be formed individually and the individual components can be secured together mechanically for use as an operating delivery ampoule.

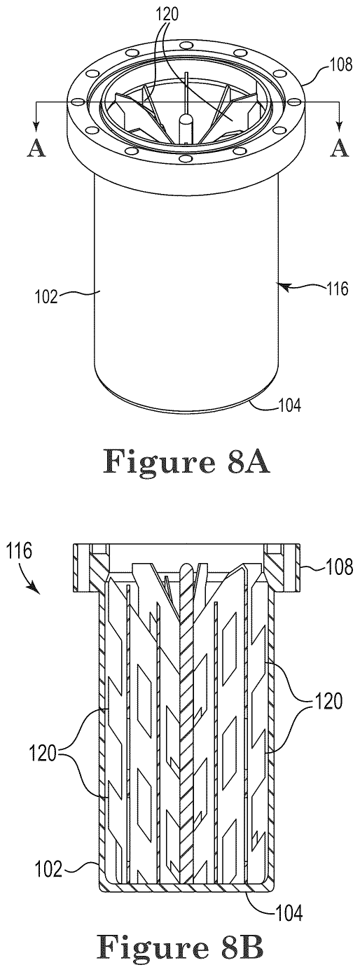

Alternately, two or more ampoule components may be combined into a single, unitary structure (“combined structure”) that is formed to include two or more of the heating element, top, bottom, and/or sidewall. An example ampoule body may include bottom and sidewall components in the form of a single, unitary (combined structure) piece (see, e.g., FIG. 8). A separate top component may be selectively removed from the sidewall and mechanically fastened to the sidewall to open or to close the ampoule. In these designs, the three-dimensional heating element may be separate from and removable from the other ampoule components and may be selectively installed within the ampoule interior and removed from the ampoule interior during assembly and use.

Alternately, a three-dimensional heating element may be a portion of a combined structure that is integrally formed with one or more other ampoule components. A combined structure that includes two or more separate ampoule components may advantageously be formed using an additive manufacturing process by which two or more ampoule components are formed together as a single, unitary combined structure. For example, a heating element may be integrally formed with and connected to a bottom, a top, a sidewall, or two or three of these, by an additive manufacturing process that forms the heating element and the bottom, the sidewall, the top, or two or all three of these components. The example combined structures may be formed with the top, bottom, sidewall, or heating element of the combined structure being not otherwise secured to each other with any additional structure or additional assembly step such as a welding step, a mechanical connecting step (using mechanical fasteners), or a physical interlocking or adhesive connection or bond formed by a step other than the additive manufacturing process.

As described, a three-dimensional heating element may be designed to exhibit useful or advantageous structural and performance features. Example heating elements may include one or more of: an efficient yet reduced heating element volume within the ampoule interior; a desired heat distribution profile within the ampoule interior; a flow channel that delivers precursor gas to the ampoule interior; an internal source of heat energy or a heat-generating device such as an electrical heating device (e.g., a heating rod), and a form that allows efficient loading of precursor material into the ampoule interior while the heating element is positioned within the interior.

Advantageously, and particularly in comparison to precursor delivery ampoules that use multiple, removable heat-conducting trays, example three-dimensional heating elements can have a relatively small volume compared to a volume of a delivery ampoule interior. Example heating elements as described may have a volume (“heating element volume”) that is less than 30, 20, 15, 10, or 5 percent of a total volume of a delivery ampoule interior. An advantage of a smaller heating element volume is to allow for a high fill volume of precursor material within an ampoule interior. Accordingly, example delivery ampoules as described can have theoretical fill volumes of at least 70, 80, 85, 90, or 95 percent. Delivery ampoules as described can also be filled and used with the theoretical fill volume being completely or substantially completely filled with precursor material, e.g., solid powder precursor. Example delivery ampoules as described can have an actual fill volume (“fill volume”) of at least 60, 70, 80, 85, 90, or 95 percent, meaning that the delivery ampoule contains at least 60, 70, 80, 85, 90, or 95 percent (by volume, bulk) solid precursor material (e.g., solid precursor powder) based on the total volume of the ampoule interior.

While exhibiting a low heating element volume, a three-dimensional heating element as described is also capable of distributing heat energy within the ampoule interior over a useful or advantageously-effective heat distribution profile throughout the vertical, radial, and circumferential space of an ampoule interior. An interior volume of a delivery ampoule may be referred to using a cartesian coordinate system having x, y, and z dimensions (length, width, and height), or may alternately be referred to using a cylindrical coordinate system that uses r, θ, and z as coordinates. The “r”-coordinate represents a radial distance from a central vertical axis of a cylindrical ampoule interior. The “z”-coordinate is a location along a height of the ampoule interior. The “θ”-coordinate is an angle (between 0 and 360 degrees) in a horizontal plane about a central vertical axis.

Useful or preferred heating elements can be adapted to produce a heat distribution profile within the ampoule interior that produces a comparatively steady, uniform, consistent flux of gaseous precursor being delivered from the ampoule.

According to certain examples, a heating element may include an array (or multiple arrays) of heating element segments that are relatively evenly distributed throughout a three-dimensional volume of a delivery ampoule interior, to provide a relatively uniform heat distribution profile throughout the ampoule interior, e.g., multiple heating element segments are located within the ampoule interior with relatively uniform and even spacing in multiple dimensions.

Alternately, as desired or needed, a heating element may have a design and may be positioned within an ampoule interior to selectively deliver heat in a non-uniform fashion within an ampoule interior. For example, a heating element may deliver a greater amount of heat energy to one portion of the ampoule interior relative to a second portion of the ampoule interior. E.g., an upper region (in the “z”-dimension) may receive a greater amount of heat energy compared to a lower region (or vice versa); alternately or optionally, an inner region (nearer to a central axis in the “r”-dimension) may receive a greater amount of heat energy compared to an outer region (farther from a central axis in the “r”-dimension). Such a non-uniform heat distribution profile may be effective to improve the uniformity of heat delivered to a precursor material, or to provide improved consistency or uniformity of a flux of gaseous precursor delivered from the precursor delivery ampoule.

A three-dimensional heating element as described can be made of a material that has high thermal conductivity to efficiently distribute heat energy within the delivery ampoule. The heat energy may be generated externally, meaning outside of the delivery ampoule, and delivered to the ampoule interior by transferring heat energy via a thermal conduction mechanism through the ampoule body to the ampoule interior and the heating element. Alternately, heat energy may be delivered to or generated by or within a heating element and delivered more directly to the ampoule interior, without the heat energy being passed by thermal conduction from an external heat source through the ampoule body (e.g., sidewall).

Heat that is generated outside of the delivery ampoule by an external heat source may be generated and delivered to the ampoule body by any useful arrangement, such as by a heating jacket or other heating device that surrounds the delivery ampoule, or by an oven that contains the delivery ampoule. Heat that is generated outside of the delivery ampoule passes by a thermal conduction mechanism through the ampoule body (sidewall, bottom, or top) into the ampoule interior and is further conducted through the heating element and distributed throughout the ampoule interior. The heating element may be in thermal contact with (e.g., structurally connected to) the ampoule body (e.g., sidewall, bottom, or top) to allow heat that passes through the ampoule body to flow by conduction to the heating element and be distributed throughout the ampoule interior.

Alternately, by other example methods and delivery ampoule designs, heat energy may be generated within the heating element and delivered directly through the heating element into the ampoule interior without the heat energy being passed through the ampoule body by conduction. For example, a heating element made of electrically-conductive material (e.g., metal) may be designed to conduct a flow of electric current through the heating element to generate heat within the heating element. Electric current passes through the heating element to generate heat within the heating element, and the heat is delivered directly from the heating element to the ampoule interior without being conducted through the ampoule body.

As another alternative, a three-dimensional heating element may contain or incorporate an electrically-resistive heating device (e.g., a heating rod) that is an integrated or a removable component of the three-dimensional heating element. An electrically-resistive heating device such as a heating rod or similar heating device generates thermal energy within the heating element, and the heat energy then flows by thermal conduction through the heating element into the ampoule interior. By this method, the heat is generated within the ampoule interior, i.e., within the heating element contained in the ampoule interior, and is not required to flow by thermal conduction through the ampoule body from an external heat source. According to certain examples, the heating element may contain a hollow space that accommodates the electrically-resistive heating device (e.g., heating rod), which can be selectively placed within the hollow space and removed from the hollow space.

Alternately or additionally, a heating element may include a hollow opening or space in the form of an enclosed flow channel (e.g., enclosed conduit) that is adapted to connect to a source of carrier gas at a location exterior to delivery ampoule. Such a flow channel can be adapted to carry a flow of carrier gas from an external source into the ampoule interior through the three-dimensional heating element. The flow channel may extend to multiple carrier gas outlets that are distributed at different locations on the heating element to deliver and distribute the carrier gas throughout the ampoule interior.

A heating element as described can have a three-dimensional structure of any form that provides efficient delivery of heat energy within a delivery ampoule interior, preferably or advantageously while having a relatively low heating element volume.

Generally, a three-dimensional heating element structure may include one or multiple arrays of spatially-distributed, connected, dis-connected, or interposed heating element segments that together deliver heat energy throughout an ampoule interior. A “heating element segment” is a thermally-conductive structure that has dimensions of length, width, and thickness. Two examples of heating element segments may be referred to as “elongate” heating element segments, and “two-dimensional” heating element segments.

An “elongate” heating element segment can have a substantially elongate form that has a single (e.g., “length”) dimension that is significantly greater than its two transverse dimensions (width, thickness). Example structures may be referred to as a “rod,” a “bar,” a “stem,” a “branch,” a “trunk,” an “arm,” or the like, having a length dimension that is at least 3, 5, 10, or 25 times greater than each of the two transverse dimensions. An elongate heating element segment may be significantly straight or may be shaped to include one or more bends, curves, spirals, or the like.

A “two-dimensional” heating element segment can have a substantially two-dimensional, flat or planar form having two dimensions (e.g., “length” and “width”) that are both significantly greater than a third dimensions (“width”). Examples include structures referred to as a “fin,” “petal,” “blade,” “leaf,” or the like, having both a length dimension and a width dimension that is at least 5, 10, or 25 times greater than a thickness dimension. A two-dimensional heating element segment such as a “fin” or a “blade” may be significantly flat and planar or may be bent or curved.

As a general consideration to allow precursor material to be efficiently loaded into an ampoule interior, a heating element and individual heating element segments may preferably be shaped and positioned within an ampoule interior to allow precursor material, particularly solid (e.g., granular powder) precursor material, to be introduced through a top of an ampoule body and flow freely in a downward direction, past or over the heating element segments, to completely or substantially completely fill the space of the theoretical fill volume of the delivery ampoule. Preferred heating elements and heating element segments will allow solid precursor material that is introduced through a top segment of the ampoule body, e.g., through a fill port, to flow freely (optionally with agitation of the delivery ampoule) from the top of the ampoule interior to the bottom of the ampoule interior and to accumulate within the ampoule interior to substantially or completely fill the theoretical fill volume of the ampoule interior. Example delivery ampoules allow for solid precursor powder to be loaded into the interior in this manner to fill at least 80, 90, or 95 percent of the theoretical fill volume of the delivery ampoule interior.

As a non-limiting example, one particular type of heating element structure can be referred to as a “stem-and-branch” heating element. A stem-and-branch heating element includes a vertical elongate heating element segment (“stem segment”) that connects to multiple elongate branch segments that individually extend radially and optionally vertically (in a z-dimension) from the stem segment. The stem segment is an elongate heating element segment that extends in a significantly vertical direction (a height direction or a z-dimension) within the ampoule interior between the top and the bottom of the delivery ampoule. A stem segment may have a length (vertically) that extends along a significant portion of the height of the ampoule interior, e.g., a length that extends between the top and bottom of the ampoule interior over at least 50, 60, 70, 80, or 90 percent of the height.

Multiple individual elongate “branch segments” extend from the stem segment. Using cylindrical coordinates relative to a vertical stem segment (which may optionally but not necessarily be located at a central axis of an ampoule interior), individual branch segments may extend at different radial angles (the θ-coordinate) about the vertical stem segment, and may extend from the stem segment at multiple locations along the height (the z-dimension) of the vertical stem segment. Individual branch segments may also extend to equal or un-equal lengths (in the r-dimension) from the stem segment. The elongate branch segments may be straight or curved and may be oriented to aligned with a horizontal dimension of the ampoule interior (e.g., substantially parallel to the ampoule bottom), or may be inclined, slanted, or curved relative to the horizontal dimension.

The heating element segments of a stem-and-branch-type heating element can be designed and positioned within an ampoule interior to allow solid precursor powder that is loaded into the ampoule interior through a top component to flow into and to completely or substantially completely fill the space of the theoretical fill volume of the ampoule. While horizontal heating element segments may be used, such as horizontally-oriented branch segments, these horizontal segments may be elongate and thin and may be spaced to allow solid precursor powder to flow downward past the branch segments to substantially or completely fill the volume of the ampoule interior that surrounds the elongate branch segments.

As another non-limiting example, a three-dimensional heating element may include multiple two-dimensional heating element segments, e.g., “fin-shaped” heating element segments, which have a substantially planar (alternately curved) form with a small thickness and a significantly larger width and length. A fin-shaped heating element segment may be thermally connected to an elongate stem segment, which may optionally (but not necessarily) be located at a central axis of an ampoule interior. A fin-shaped heating element segment may alternately or additionally be thermally connected to a sidewall, a top, a bottom, or two or more of these components of an ampoule body, and extend radially (in an r-dimension), vertically (in a z-dimension), or both, from a connection to the sidewall, bottom, or top component into the ampoule interior at different radial angles (the θ-coordinate) and heights relative to a central vertical axis of the ampoule interior.

According to certain examples, a heating element may include multiple fin-shaped heating element segments that originate from an elongate stem segment at a central axis of an ampoule interior and extend toward the sidewall, and may also contain additional fin-shaped heating element segments that originate from a sidewall component and extend toward the central axis. The heating element segments that originate from the stem segment may be interposed with (located in spaces between) the heating element segments that originate from the sidewall.

Alternately or additionally, a heating element may include multiple fin-shaped heating element segments that originate from a top component of an ampoule and extend toward a bottom component, and additional interposed fin-shaped heating element segments that originate from the bottom component and extend toward the top component.

To efficiently load solid precursor powder into the ampoule interior, two-dimensional (e.g., fin-shaped) heating element segments may be shaped and positioned to allow solid precursor powder introduced through a top component of an ampoule to flow freely in a downward direction, past or over the two-dimensional heating element segments, optionally with agitation, to substantially or completely fill the space of the theoretical fill volume of the ampoule. For example, while two-dimensional heating elements may include a horizontally-oriented surface, most or all of any two-dimensional heating element segments of a heating element may be oriented non-horizontally within the ampoule interior.

The described examples of heating elements and heating element segments are non-limiting, and various other forms of heating element segments may be useful, as will be appreciated, to perform as described herein. These include flat, contoured, coiled, helical, angled, or curved heating element structures that may be vertically or horizontally-oriented, apertured plates, mesh segments, fenestrated segments, or other structures that can be arranged within an ampoule interior to deliver or conduct heat throughout an ampoule interior. Non-limiting examples of heating elements of the present description and their use in as a component of a delivery ampoule are shown in the figures and described.

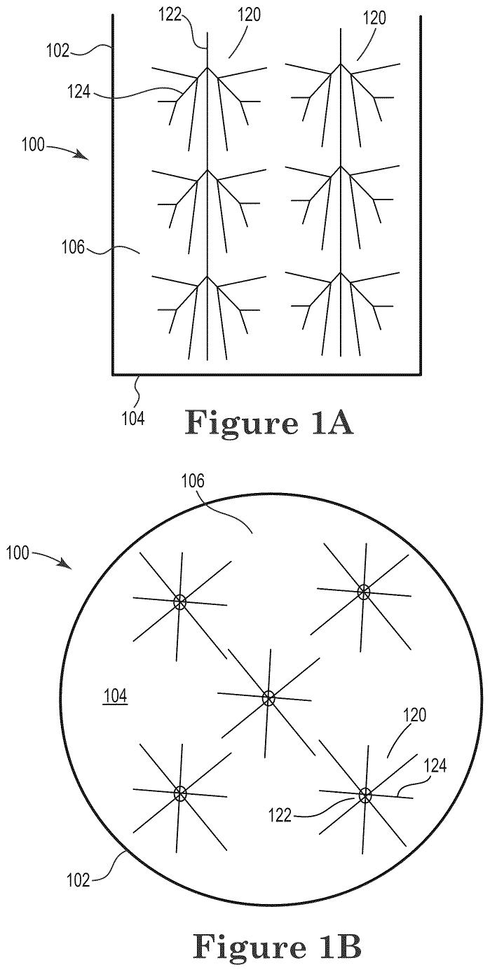

FIG. 1A (side cross-section view) and 1B (top view) show components of example delivery ampoule 100 that includes heating element 120, which includes multiple arrays of “stem-and-branch”-type heating elements as described. Ampoule 100 includes sidewall 102 and bottom 104 which, with a top (not shown), define ampoule interior 106. The top may be a structure that is separate and removable from sidewall 102 and heating element 120 or may be component of a combined structure that includes the top integrally formed with heating element 120, sidewall 102, or both, by an additive manufacturing process to form a unitary structure. Each array of heating element 120 includes a vertical elongate stem segment 122 and multiple elongate branch segments 124 that are connected to and extend radially from stem segment 122.

In use, solid precursor powder (not shown) can be loaded into interior 106 and a top component (not shown) of ampoule 100 can then be placed over interior 106 and sidewall 102 to seal interior 106. Alternatively, with a top component mechanically secured to sidewall 102, or with a top component being a component of a combined structure of ampoule 100, and with interior 106 sealed, solid precursor powder can be poured or otherwise caused to flow through the top component (not shown), e.g., through a fill port in the top component, into interior 106, to substantially or completely fill interior 106 with the solid precursor powder.

In use to produce a gaseous precursor, heating element 120 and ampoule 100 may be heated by an external source of heat located outside of ampoule 100, e.g., by placing ampoule 100 in an oven or by surrounding ampoule 100 with an external heat source such as a heating jacket. While not illustrated, each array of heating element 120 may be in thermal contact with (e.g., structurally connected to) a component of ampoule 100 (top, bottom, or sidewall) and heat energy can be transferred by thermal conduction through the top, bottom, or sidewall to heating element 120, which then conducts the heat throughout interior 106.

According to other examples, heating element 120 or one or more of the individual arrays of heating element 120 may include an internal heating mechanism such as a heating rod (not shown) that is capable of generated heat within heating element 120 and within interior 106. The heat energy produced by the internal heating mechanism can be transferred by thermal conduction through heating element 120, which then delivers the heat energy throughout interior 106.

Optionally but not shown, heating element 120 may include one or more flow channels that receive carrier gas from an external source (not shown) and distribute the carrier gas via multiple carrier gas outlets (not shown) that are located at multiple positions on the surface of heating element 120, to distribute the carrier gas throughout interior 106. In some instances, the flow channels are formed in the heating element 120 such that they are configured to direct the flow of carrier gas through the interior 106 in a direction flowing from a bottom to a top of the ampoule.

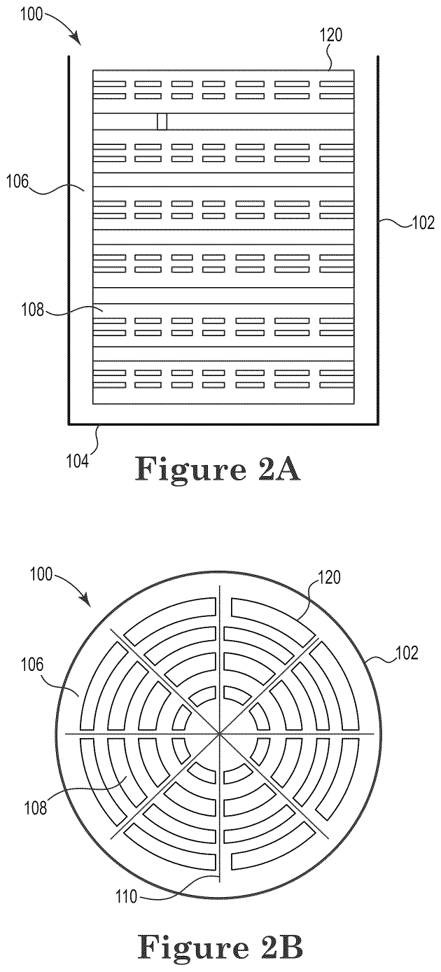

FIGS. 2A (side cross-section view) and 2B (top view) show components of example delivery ampoule 100 that contains an alternate design of heating element 120. Example heating element 120 of FIGS. 2A and 2B includes thermally conductive heating element segments as described herein. As illustrated, heating element 120 may include multiple horizontally-extending, vertically-arranged ring-shaped heating element segments 108 that are located within interior 106, in combination with radially-extending spoke-like elongate heating element segments 110. Heating element segments 108 and 110 may be connected vertically and horizontally to distribute heat energy by thermal conduction throughout interior 106.

In use, solid precursor powder (not shown) can be loaded into interior 106 and a top (not shown) can be placed over sidewall 102 to seal interior 106. Alternately, with the top component covering interior 106, solid precursor powder can be poured or otherwise delivered into interior 106, e.g., through a fill port in the top, to substantially or completely fill interior 106 with the precursor powder.

Example heating element 120 and ampoule 100 of FIGS. 2A and 2B may be heated by an external source of heat located outside of ampoule 100, e.g., by placing ampoule 100 in an oven or by surrounding ampoule 100 with an external heat source such as a heating jacket. Heating element 120, e.g., through one or more of heating element segments 108 or 110, may be in thermal contact with a component of ampoule 100 (top, bottom, or sidewall) to transfer heat energy by thermal conduction from ampoule 100 to heating element 120, which then conducts the heat energy throughout interior 106. Alternately, heating element 120 may include an internal heating mechanism such as a heating rod (not shown) or other electrically-resistive heating device that is adapted to generate heat within heating element 120 and, thereby, within ampoule interior 106.

Optionally heating element 120 may include a flow channel that receives carrier gas from an external source of carrier gas (not shown) and the carrier gas can be carried through the flow channel to multiple carrier gas outlets that are included at multiple locations of heating element 120, to distribute and delivery the carrier gas throughout interior 106. In some embodiments, the flow channels are formed in the heating element 120 such that they are configured to direct the flow of carrier gas through the interior 106 in a direction flowing from a bottom to a top of the ampoule.

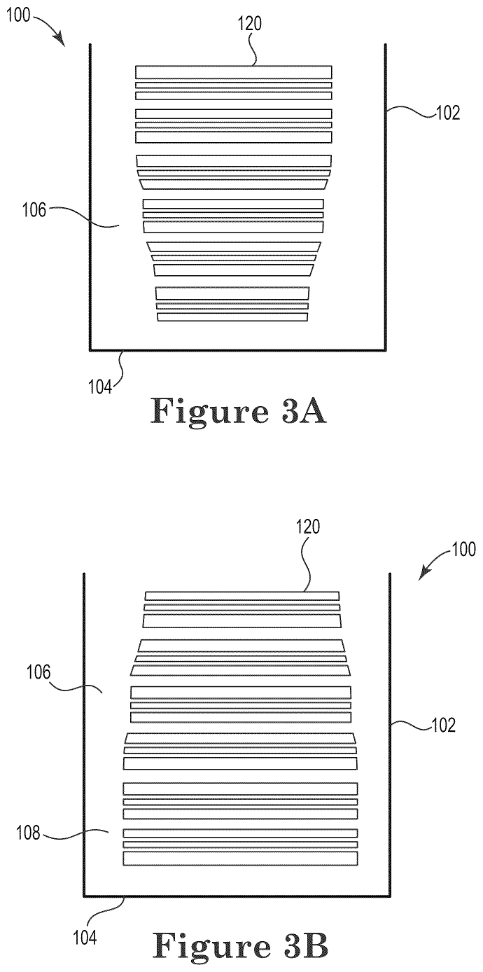

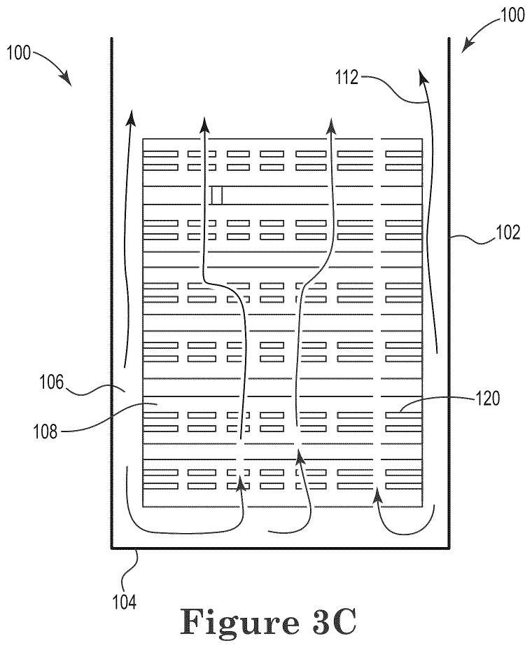

FIGS. 3A and 3B (side cross-sectional views) show components of an example delivery ampoule 100 that includes heating element 120, which may exhibit features and be used as described herein, e.g., with respect to example heating elements 120 of FIGS. 3A and 3B. According to the examples of FIGS. 3A and 3B, a heating element may be designed to produce a non-uniform heat distribution profile within interior 106. Heating element 120 of FIG. 3A is adapted to deliver a greater amount of heat energy at an upper region of interior 106 and a smaller amount of heat energy at a lower region of interior 106. To achieve this effect, heating element 120 is tapered to have a larger dimension at the upper region and a smaller dimension at the lower region. Conversely, heating element 120 of FIG. 3B is adapted to deliver a greater amount of heat energy at a lower region of interior 106 and a smaller amount of heat energy at 6 upper region of interior 106. Heating element 120 is tapered to have a smaller dimension at the upper region and a larger dimension at the lower region.

FIG. 3C shows components of an example delivery ampoule 100 that includes heating element 120, which may exhibit features and be used as described herein, e.g., with respect to example heating element 120 of FIGS. 3A and 3B. According to the example of FIG. 3C, heating element 120 may be designed to include a customized path of carrier gas through ampoule interior 106 and through the heating device 120 to produce a desired, constant or uniform flux of carrier gas being delivered from the ampoule. Heating element 120 of FIG. 3 A includes horizontal heating segments 108, which include openings or spaces between the horizontal heating elements. The spaces between and through heating segments 108 can be formed and positioned to allow a desired flow of carrier gas 112 (arrows) through interior 106 to produce a uniform flow or flux of carrier gas from delivery ampoule 100.

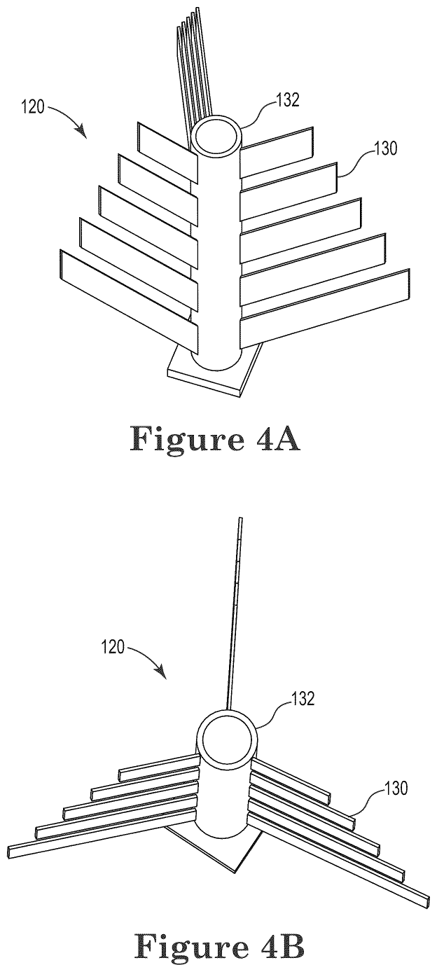

FIGS. 4A and 4B are top side perspective views of an example three-dimensional heating element 120 as described, prepared by an additive manufacturing method. Heating element 120 includes multiple fin-shaped (or elongate) heating element segments 130 extending radially and vertically at an upward angle from stem segment 132. In some cases, stem segment 132 can be a hollow stem segment 132 adapted to receive a heater rod. Heating element 120 is formed as a single (integral) component piece made of multiple heating element segments 130 connected to stem segment 132; heating element segments 130 and stem segment 132 were formed together as a single, unitary combined structure during an additive manufacturing process. Optionally, not illustrated, heating element 120 can be formed as a combined structure that includes heating element 120 and one or more of a sidewall, a bottom, and a top of a precursor delivery ampoule.

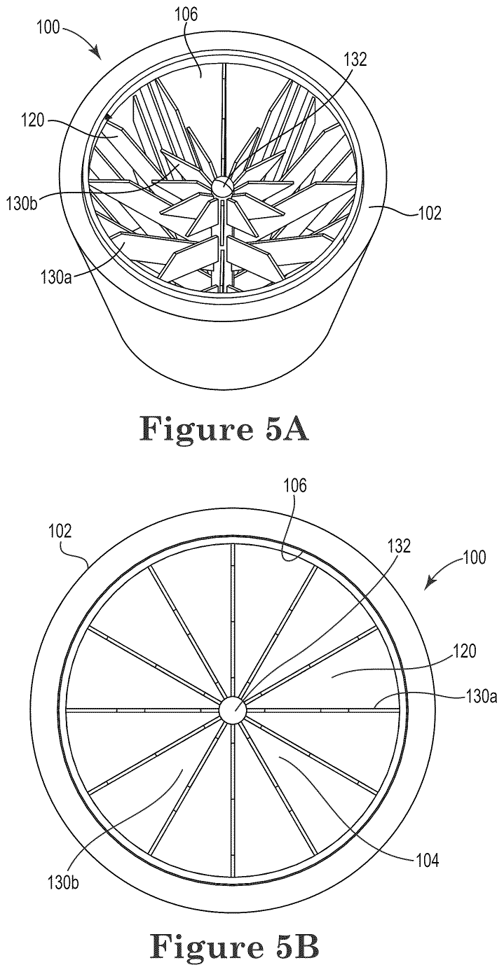

FIGS. 5A and 5B are a top perspective view and a top view of an example three-dimensional precursor delivery ampoule 100 that includes heating element 120 contained at ampoule interior 106 which is defined by sidewall 102, bottom 104, and a top (not shown). Heating element 120 includes multiple fin-shaped (or elongate) heating element segments 130a and 130b. Heating element segments 130a are connected to sidewall 120 and extend radially inward toward stem segment 132. Heating element segments 130b are connected to stem segment 132 and extend radially outward toward sidewall 102. Heating element 120, which includes heating element segments 130a and 130b, and stem segment 132, is formed with sidewall 102 and bottom 104 as a single, unitary combined structure by an additive manufacturing process.

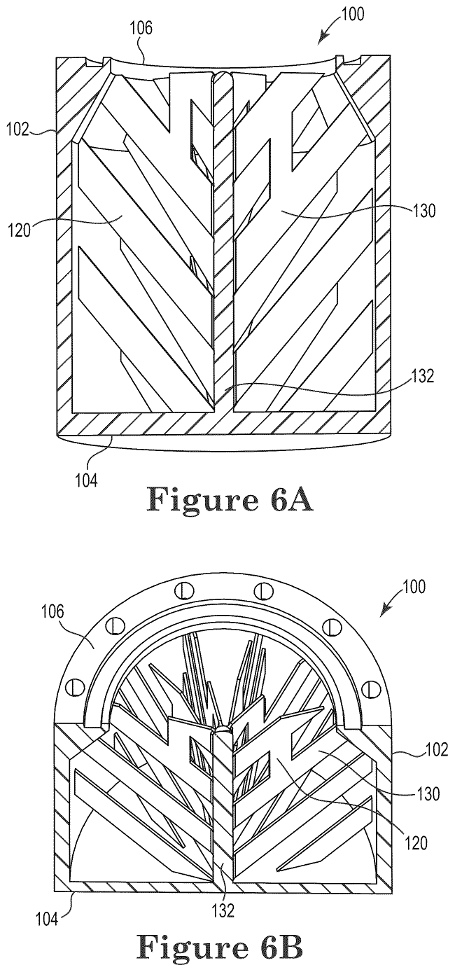

FIGS. 6A and 6B are a side cut-away view and a top perspective cut-away view of an example three-dimensional precursor delivery ampoule 100 that includes heating element 120 contained at ampoule interior 106 which is defined by sidewall 102, bottom 104, and a top (not shown). Heating element 120 includes multiple fin-shaped (or elongate) heating element segments 130, which are individually connected to one or more of sidewall 120, sidewall 102, and bottom 104. Heating element 120, which includes heating element segments 130 and stem segment 132, is formed with sidewall 102 and bottom 104 as a single, unitary combined structure by an additive manufacturing process.

In each of the embodiments described herein with reference to FIGS. 4A-6B, heating element 120 and ampoule 100 may be heated by an external source of heat located outside of ampoule 100 or may include an internal heating mechanism such as a heating rod (not shown) to generate heat within heating element 120. Optionally, heating element 120 may include one or more flow channels that receives carrier gas from an external source of carrier gas (not shown) and the carrier gas can be carried through the flow channel(s) to multiple carrier gas outlets that are included at multiple locations of heating element 120. In some embodiments, the one or more flow channels are formed in the heating element 120 such that they are configured to direct the flow of carrier gas through the interior 106 in a direction flowing from a bottom to a top of the ampoule. In some cases, one or more flow channels may also be formed in the top of the ampoule such that they are in fluid communication with one or more flow channels formed in the heating element.

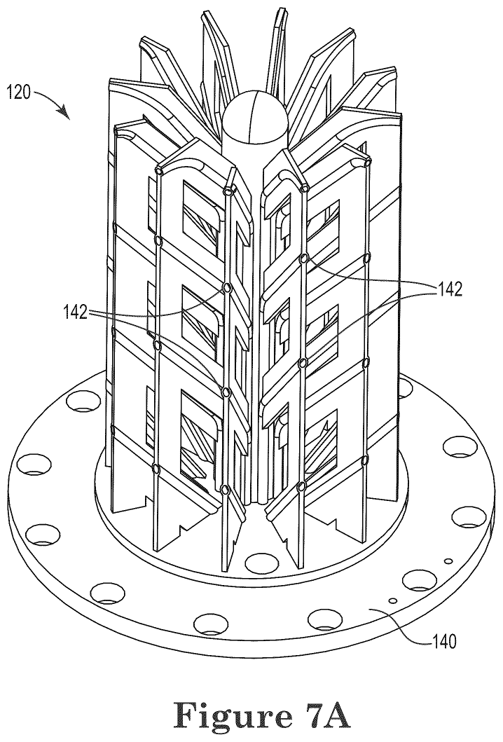

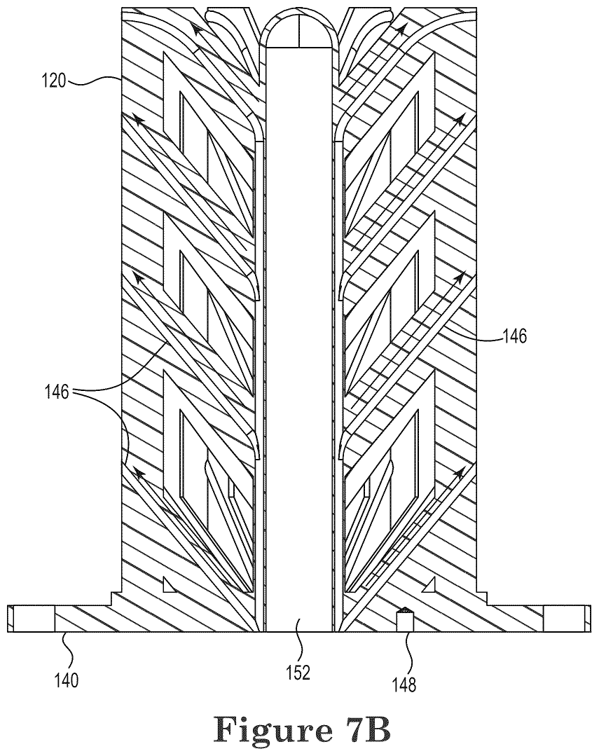

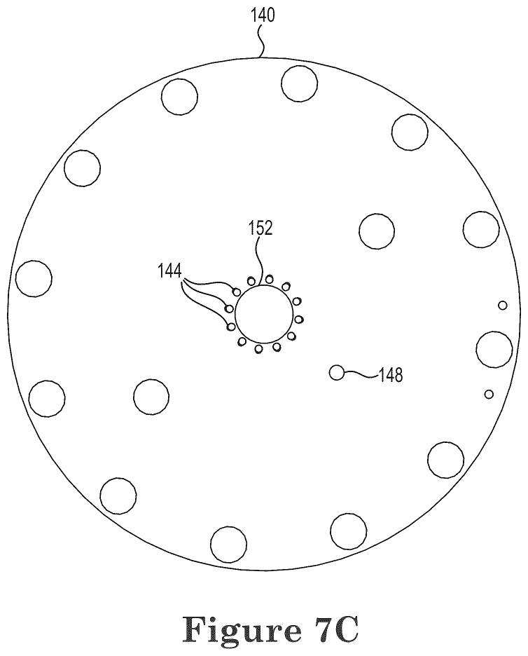

FIGS. 7A and 7B shows an exemplary heating element 120 including one or more flow channels 146 (FIG. 7B) that are configured to direct the flow of carrier gas to multiple carrier gas outlets 142, as described herein. In some embodiments, the one or more carrier gas outlets 142 are positioned on the heating element 120 such that they are configured to direct the flow of carrier gas through the interior 106 in a direction flowing from a bottom to a top of the ampoule. Additionally, as shown in FIGS. 7B and 7C, heating element 120 can include stem segment 132 defining a hollow cavity 152 that is adapted to receive a heater rod, as describe herein. According to some embodiments, as shown in FIG. 7A, heating element 120, which includes stem segment 132, can be formed with a top 140 of an ampoule as a single, unitary combined structure by an additive manufacturing process. In other embodiments, heating element 120, including stem segment 132, can be formed with a bottom and/or a sidewall of an ampoule body using an additive manufacturing process.

FIG. 7C shows a top view of top 140. In one example, as shown in FIG. 7A, top 140 may be integrally formed with the heating element 120 to form a unitary combined structure, as described herein. In another example, top 140 can be provided as separate individual component. In either example, top 140 can include one or more carrier gas inlets 144 for introducing a carrier gas into the ampoule. The one or more carrier gas inlets 144 formed in the top 140 can be in fluid communication with one or more flow channels defined in the heater element 120 (elements 146 in FIG. 8B). A carrier gas can be introduced into the ampoule via the carrier gas inlets 144 such that it travels from any fluid channels formed in the top into the fluid channels formed in the heater element 120 and out the carrier gas outlets 142 into the ampoule interior. Upon sublimation of the solid precursor material contained within the ampoule, vapor may be delivered from the ampoule interior via a vapor delivery port 148.

FIGS. 8A and 8B show different views of an of exemplary precursor delivery ampoule 116. Ampoule 116 is a 3D printed ampoule that is prepared as a single, unitary combined structure by an additive manufacturing method. As a result of its method of manufacture, the precursor ampoule 116 is a single, unitary combined structure with bottom 104, sidewall 102, top flange 108, and heating elements (fins) 120 integrally formed together such that subsequent welding or mechanical attachment is not required.

### ASPECTS

Aspect 1 relates to a precursor delivery ampoule adapted to generate a gaseous precursor useful in a vapor deposition process, the ampoule comprising: an ampoule body comprising a sidewall, a top, and a bottom that define an ampoule interior, an outlet port that allows gaseous precursor to flow out of the ampoule interior, a three-dimensional thermally-conductive heating element contained in the ampoule interior, the heating element being prepared by an additive manufacturing method.

Aspect 2 includes the delivery ampoule of aspect 1, wherein the heating element has a heating element volume of less than 30 percent of the ampoule volume.

Aspect 3 includes the delivery ampoule of aspects 1 or 2, having a theoretical fill volume of at least 70 percent.

Aspect 4 includes the delivery ampoule of any of aspects 1 through 3, comprising a carrier gas inlet port that allows carrier gas to pass from an exterior of the ampoule body into the ampoule interior.

Aspect 5 includes the delivery ampoule of any of aspects 1 through 4, wherein the heating element comprises an electrically-resistive heating device.

Aspect 6 includes the delivery ampoule of any of aspects 1 through 5, wherein the heating element comprises a flow channel adapted to deliver carrier gas to the ampoule interior.

Aspect 7 includes the delivery ampoule of any of aspects 1 through 6, wherein the heating element comprises an elongate stem segment and multiple elongate segments extending radially from the elongate stem segment.

Aspect 8 includes the delivery ampoule of aspect 7, wherein the elongate segments extend radially from the stem segment at multiple locations along a height of the delivery ampoule.

Aspect 9 includes the delivery ampoule of any of aspects 1 through 6, wherein the heating element comprises multiple two-dimensional heating element segments.

Aspect 10 includes the delivery ampoule of any of claims 1 through 9, containing solid precursor material at the ampoule interior.

Aspect 11 includes the delivery ampoule of aspect 10, wherein the ampoule interior contains at least 60 percent (volume, bulk) solid precursor material based on total volume of the ampoule interior.

Aspect 12 includes the delivery ampoule of any of aspects 1 through 9, wherein the interior containing the heating element can be filled with solid precursor material by introducing a flow of solid precursor material to the ampoule interior from above the interior, whereby the solid precursor material flows to the bottom of the ampoule interior and accumulates within the interior to fill at least 60 percent of a theoretical fill space of the ampoule interior.

Aspect 13 includes the delivery ampoule of any of aspects 1 through 12, wherein the heating element and the top are a combined structure prepared by the additive manufacturing method.

Aspect 13 includes the delivery ampoule of any of aspects 1 through 13, wherein the heating element and the sidewall are a combined structure prepared by the additive manufacturing method.

Aspect 15 includes the delivery ampoule of any of aspects 1 through 13, wherein the heating element and the bottom are a combined structure prepared by the additive manufacturing method.

Aspect 16 includes the delivery ampoule of any of aspects 1 through 15, wherein the sidewall and the bottom are a combined structure prepared by the additive manufacturing method.

Aspect 17 relates to a vapor deposition device comprising a delivery ampoule of any of aspects 1 through 16.

Aspect 18 relates to a method of making a three-dimensional heating element of a precursor delivery ampoule of any of aspects 1 through 16 by an additive manufacturing method.

Aspect 19 relates to a method of delivering gaseous precursor to a vapor deposition device, the method comprising: placing precursor material into an interior of precursor delivery ampoule comprising: an ampoule body comprising a sidewall, a top, and a bottom that define an ampoule interior, an outlet port that allows gaseous precursor to flow out of the ampoule interior, a three-dimensional thermally-conductive heating element contained in the ampoule interior, the heating element being prepared by an additive manufacturing method, sealing the ampoule interior, heating the precursor material to produce gaseous precursor, and delivering the gaseous precursor from the interior to a vapor deposition device.

Aspect 20 relates to the method of aspect 19, including the precursor delivery ampoule comprising a carrier gas inlet port, the method comprising delivering carrier gas from an exterior of the ampoule body into the ampoule interior.

Aspect 21 relates to the method of aspect 19, including the heating element comprising a flow channel, the method comprising delivering the carrier gas to the ampoule interior through the flow channel.

Aspect 22 relates to the method of aspect 19, including the heating element comprising an electrically-resistive heating device, the method comprising generating heat by passing electric current through the electrically-resistive heating device and delivering the heat to the ampoule interior.

Aspect 23 relates to the method of any of aspects 19 through 22, including the top comprising a precursor fill port, the method comprising delivering solid precursor material to the ampoule interior through the precursor fill port.

Aspect 24 relates to the method of claim 23 comprising introducing a flow of solid precursor material to the ampoule interior through the fill port, whereby the solid precursor material flows to the bottom of the ampoule interior and accumulates within the interior to fill at least 80 percent of a theoretical fill volume of the ampoule.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Accordingly, in any one or more of the embodiments disclosed herein, a particular structural component being disposed between two other structural elements can be: disposed directly between both of the two other structural elements such that the particular structural component is in direct contact with both of the two other structural elements; disposed directly next to only one of the two other structural elements such that the particular structural component is in direct contact with only one of the two other structural elements; disposed indirectly next to only one of the two other structural elements such that the particular structural component is not in direct contact with only one of the two other structural elements, and there is another element which is disposed between the particular structural component and the one of the two other structural elements; disposed indirectly between both of the two other structural elements such that the particular structural component is not in direct contact with both of the two other structural elements, and other features can be disposed therebetween; or any combination(s) thereof.

1. A precursor delivery ampoule adapted to generate a gaseous precursor useful in a vapor deposition process, the ampoule comprising:
an ampoule body comprising a sidewall, a top, and a bottom that define an ampoule interior,
an outlet port that allows gaseous precursor to flow out of the ampoule interior,
a three-dimensional thermally-conductive heating element contained in the ampoule interior, the heating element being prepared by an additive manufacturing method.

2. The delivery ampoule of claim 1, the heating element having a heating element volume of less than 30 percent of the ampoule volume.

3. The delivery ampoule of claim 1, having a theoretical fill volume of at least 70 percent.

4. The delivery ampoule of claim 1, comprising a carrier gas inlet port that allows carrier gas to pass from an exterior of the ampoule body into the ampoule interior.

5. The delivery ampoule of claim 1, wherein the heating element comprises a flow channel adapted to deliver carrier gas to the ampoule interior.

6. The delivery ampoule of claim 1, wherein the heating element comprises an elongate stem segment and multiple elongate segments extending radially from the elongate stem segment.

7. The delivery ampoule of claim 1, containing solid precursor material at the ampoule interior.

8. The delivery ampoule of claim 1, wherein the ampoule interior contains at least 60 percent (volume, bulk) solid precursor material based on total volume of the ampoule interior.

9. The delivery ampoule of claim 1, wherein the interior containing the heating element can be filled with solid precursor material by introducing a flow of solid precursor material to the ampoule interior from above the interior, whereby the solid precursor material flows to the bottom of the ampoule interior and accumulates within the interior to fill at least 60 percent of a theoretical fill space of the ampoule interior.

10. The delivery ampoule of claim 1, wherein the heating element and the top are a single, unitary combined structure prepared by the additive manufacturing method.

11. The delivery ampoule of claim 1, wherein the heating element and the sidewall are a single, unitary combined structure prepared by the additive manufacturing method.

12. The delivery ampoule of claim 1, wherein the heating element and the bottom are a single, unitary combined structure prepared by the additive manufacturing method.

13. The delivery ampoule of claim 1, wherein the sidewall and the bottom are a single, unitary combined structure prepared by the additive manufacturing method.

14. A method of delivering gaseous precursor to a vapor deposition device, the method comprising:
placing precursor material into an interior of precursor delivery ampoule comprising:
an ampoule body comprising a sidewall, a top, and a bottom that define an ampoule interior,
an outlet port that allows gaseous precursor to flow out of the ampoule interior,
a three-dimensional thermally-conductive heating element contained in the ampoule interior, the heating element being prepared by an additive manufacturing method,
sealing the ampoule interior,
heating the precursor material to produce gaseous precursor,
delivering the gaseous precursor from the interior to a vapor deposition device.

15. The method of claim 14, the precursor delivery ampoule comprising a carrier gas inlet port, the method comprising delivering carrier gas from an exterior of the ampoule body into the ampoule interior.

16. The method of claim 14, the heating element comprising a flow channel, the method comprising delivering the carrier gas to the ampoule interior through the flow channel.

17. The method of claim 14, the heating element comprising an electrically-resistive heating device, the method comprising generating heat by passing electric current through the electrically-resistive heating device and delivering the heat to the ampoule interior.

18. The method of claim 14, the top comprising a precursor fill port, the method comprising delivering solid precursor material to the ampoule interior through the precursor fill port.

19. The method of claim 18 comprising introducing a flow of solid precursor material to the ampoule interior through the fill port, whereby the solid precursor material flows to the bottom of the ampoule interior and accumulates within the interior to fill at least 80 percent of a theoretical fill volume of the ampoule.
